(19) United States
(12) Patent Application Publication
(10) Pub. No.: US 2006/0121357 A1
(43) Pub. Date: Jun. 8, 2006

(54) Large pattern printing

(75) Inventor: Francis Stace Murray Clube, Neuchatel (CH)

Correspondence Address: Holtronic Technologies Plc., c/o Champs-Montants 12b, Marin, CH-2074, CH

(73) Assignee: Holtronic Technologies Plc.

(21) Appl. No.: 11/015,122

(22) Filed: Dec. 2, 2004

(51) Int. Cl. G03F 7/00

(52) U.S. Cl. 430/1; 430/2

(57) ABSTRACT

A method for printing a large pattern onto a substrate which includes decomposing the large pattern into a plurality of pattern segments; providing a mask in which is arranged one of each distinctive pattern segment; recording a hologram mask of the mask; providing a TIR holographic lithography machine with an exposure system for discretely reconstructing with a scanning illumination beam the distinct pattern segments recorded in the hologram mask, and with a substrate positioning system for laterally displacing the substrate with respect to the hologram mask; arranging the substrate and the hologram mask in the lithographic machine; displacing the substrate to a first lateral position with respect to the hologram mask and discretely printing the first pattern segment at a first location on the substrate; and repeating this for the different pattern segments recorded in the hologram mask until the large pattern has been printed onto the substrate.

The present invention relates to the field of total internal reflection (TIR) holography, and in particular to TIR holography as employed for photolithography.

The prior art teaches that an important application of TIR holography is for printing high-reslution microcircuit patterns, especially on glass substrates for manufacturing certain flat panel displays. According to the method, a hologram mask is recorded from a conventional chrome mask bearing a pattern of features by firstly placing the mask in close proximity to a holographic recording layer on a glass plate arranged on a glass prism. The mask is then illuminated with an object laser beam whilst simultaneously illuminating the holographic recording layer with a mutually coherent reference laser beam through the prism at such an angle that the reference beam is totally internally reflected from the surface of the holographic layer. The optical interference of the light transmitted by the mask with the reference beam is recorded by the photosensitive material in the holographic recording layer, which is subsequently fixed by an appropriate processing step, to form the hologram mask. The mask pattern can afterwards be regenerated, or reconstructed, from the hologram mask by re-mounting the hologram mask on a glass prism and illuminating it through the prism with a laser beam having the same wavelength as the laser beam used for recording the hologram. The pattern may be printed by placing a substrate, such as a silicon wafer or a glass plate, coated with a layer of photoresist at the same distance from the hologram as the chrome mask was during recording.

Because of the close proximity between the holographic layer and mask during recording, and between the hologram and substrate during reconstruction, the TIR holographic method provides a very high numerical aperture (I) in comparison with traditional photolithographic methods which enables a relatively high resolution features to be imaged using a given exposure wavelength, for example, 0.4 μm features may be printed with a wavelength of 364 nm. Further TIR holographic lithography possesses no trade-off between feature resolution and pattern size, so it can print, for example, a 0.4 μm-resolution pattern of dimensions 150 mm×150 mm.

Lithographic exposure equipment based on this technique has been developed and commercialised. In such a system the hologram mask is mounted to the bottom face of a 45°, 45°, 90° prism with a layer of transparent fluid between the two. The substrate to be printed is mounted to a vacuum chuck and accurately positioned with respect to the hologram by a multi-axis positioning stage. The equipment generally employs a scanning exposure mechanism by which the exposure laser beam is scanned in a raster pattern over the hologram surface in order that the intensity of the features in the pattern reconstructed from the hologram have high uniformity over the pattern area and also so that the pattern can be printed accurately in focus on a substrate whose surface may not be especially flat. This is important because high-resolution images have a limited depth of focus. For this purpose the holographic lithographic equipment also integrates a focus system which continuously measures the local separation between the hologram and substrate surfaces as the exposure beam scans across the hologram, which operates in a feed-back loop with actuators in the substrate positioning system in order the image projected from the hologram is uniformly printed in focus onto the substrate surface.

The lithographic equipment further generally integrates an alignment system to allow “higher-level” patterns recorded in hologram masks to be accurately aligned with respect to “lower-level” patterns previously printed onto the substrate surface. This is important for fabricating the complex structure of micro-circuits formed of materials with different electrical properties. The higher-level alignment marks may be recorded into the hologram mask from the chrome mask using just an object-beam exposure of the marks in the mask. The lithographic machine is typically provided with two or more alignment microscopes that image alignment marks in the hologram and on the substrate surface onto CCD detectors, and also image processing software that accurately calculates the relative positions of the hologram and substrate alignment marks. In response to these measurements actuators in the substrate positioning system displace the substrate to accurately align it, both translationally and rotationally, with respect to the hologram, following which the higher-level pattern is printed onto the lower-level pattern.

Some models of the equipment allow the pattern recorded in the hologram to be printed a number of times onto the substrate surface using a “step-and-repeat” exposure sequence, for example, a pattern of dimensions 120 mm×120 mm recorded in the hologram may be printed 12 times onto a substrate of dimensions 400 mm×500 mm. In this case the substrate positioning system also integrates large-travel translation.

The equipment may also be provided with automated substrate changing capability so that substrates can be automatically loaded from an input cassette onto the substrate positioning stage for the alignment and exposure sequence and afterwards unloaded and transferred into an output cassette.

The various substrate positioning, exposure, focussing, alignment and substrate changing operations are controlled by a central control unit with a graphical user interface allowing the machine operator to initiate individual machine operations or a completely automatic exposure cycle for substrates in an input cassette.

A drawback of TIR holographic lithography arises because the size and resolution of a pattern recorded in the hologram mask, and reconstructed therefrom on the lithographic system, are dependent on the size and resolution of the pattern that can be provided in the original chrome mask. This is because the critical technology available for manufacturing high-resolution chrome masks are laser-beam and electron-beam writing systems which generally have maximum pattern area of ˜6″×6″. Thus, although TIR holography itself is able to record larger high-resolution patterns, in practice it is limited to the dimensions achievable in the chrome mask. This presents a problem for the application of TIR holography to, for example, 17″, 21″ diagonal displays.

It is therefore an object of the present invention to provide a method and apparatus for enabling the application of TIR holographic lithography to large high-resolution patterns whose dimensions are larger than those obtainable in the original chrome mask.

According to a first aspect of the invention there is provided a method using TIR holography for printing a large final pattern onto a substrate bearing a layer of photosensitive material, which method includes the steps of:
a) decomposing the large final pattern into a plurality of pattern segments, at least one of which is repeated one or more times around the large final pattern;
b) providing a mask with a pattern in which is arranged one of each distinctive pattern segment present in the plurality of pattern segments of the decomposed large final pattern;
c) recording a hologram mask of the mask pattern;
d) arranging the hologram mask on the first face of a coupling element so that the pattern recorded therein may be reconstructed by an exposure beam passing through a second face of the coupling element;
e) providing a TIR holographic lithography machine with an exposure system for discretely reconstructing using a scanning illumination beam the individual pattern segments recorded in the hologram mask, and with a substrate positioning system for laterally displacing the substrate with respect to the hologram mask;
f) arranging the hologram mask and coupling element in the lithographic machine;
g) arranging the substrate on the substrate positioning system in the lithographic machine;
h) displacing the substrate to a first lateral position with respect to the hologram mask such that a first pattern segment recorded in the hologram mask may be printed at a first location on the substrate corresponding to that required in the large final pattern;
i) discretely reconstructing the first pattern segment recorded in the hologram mask and printing it at the first location on the substrate;
j) displacing the substrate to a second lateral position in relation to the hologram mask such that the first or another pattern segment may be printed from the hologram mask at a second location on the substrate corresponding to that required in the large final pattern;
k) discretely reconstructing said first or another pattern segment from the hologram mask and printing it at the second location on the substrate;
l) repeating steps j) and k) for all the different pattern segments recorded in the hologram mask, printing them at them at the required locations on the substrate for recomposing the large final pattern, until the large final pattern has been printed onto the substrate.

Preferably, each step of discretely reconstructing a particular pattern segment from the hologram mask includes shielding those parts of the hologram mask that reconstruct neighbouring pattern segments in order to ensure that only the desired pattern segment is reconstructed. Shielding comprises arranging an element or elements in the path of the exposure beam for blocking, reflecting or absorbing the light in the exposure beam that would otherwise illuminate those parts of the hologram mask that reconstruct neighbouring pattern segments. The step of shielding parts of the hologram mask that reconstruct neighbouring pattern elements allows the separation of the different segments of the pattern in the mask to be reduced, which increases the area available for the segments themselves. This permits the number of exposure operations for printing the large final pattern on the substrate to be minimised, which is important for maximising the machine throughput, a key consideration for lithographic equipment for the micro-electronics industry.

If the reconstruction of a particular pattern segment in the hologram mask is obtained by scanning an exposure beam across the hologram mask, as is taught and recommended in the prior art, then the shielding of neighbouring parts of the hologram mask from the exposure beam may be achieved by arranging the elements for blocking, reflecting or absorbing the light in the path of the scanning exposure beam to block, reflect or absorb light that would otherwise reconstruct neighbouring pattern segments.

Clearly, in each case the scanning area of the exposure beam should be selected in order that the particular pattern segment being reconstructed by the scanning exposure beam receives a uniform time-integrated exposure density.

Using a scanning exposure beam it is preferable that the local separation between the substrate and hologram mask where the exposure beam is illuminating the hologram is continuously measured and its longitudinal position relative to the hologram continuously adjusted in order that the pattern is accurately printed in focus onto the substrate surface.

The step of arranging the lateral position of the substrate in relation to the pattern recorded in the hologram mask is achieved by displacing the substrate in at least in one of two substantially orthogonal directions in the plane of the substrate.

For obtaining high-accuracy abutment, or stitching, between the various pattern segments printed from the hologram mask onto the substrate, the displacement of the substrate should be performed accurately and should additionally take into account, firstly, the orientation of the co-ordinate axes of the pattern recorded in the hologram mask with respect to the co-ordinate axes of the substantially orthogonal directions in which the substrate is displaced; secondly, the scales of the co-ordinate axes of the pattern recorded in the hologram mask relative to the respective co-ordinate axes of the substantially orthogonal directions in which the substrate is displaced; and, thirdly, the orthogonality error between the axes of the substantially orthogonal directions in which the substrate is displaced, that is the deviation from 90 of the angle between the two substantially orthogonal directions. For this purpose, the method of the invention should preferably include the step of determining the orientation and scales of the co-ordinate axes of the pattern recorded in the hologram with respect to the co-ordinate axes of the orthogonal directions in which the substrate is displaced, and also the step of determining the orthogonality error between of the co-ordinate axes of the substantially orthogonal directions in which the substrate is displaced. The determination of these values may be achieved using an alignment system of the type mentioned above in the section describing the prior art. Specifically, they may be determined by including at least two upper-level alignment marks in the mask pattern and recording them in the hologram mask, and providing a lower-level alignment mark directly or indirectly on the substrate positioning system which is arranged in proximity and parallel to the hologram mask; by displacing the lower-level mark it in at least one of the two substantially orthogonal directions until it is successively aligned with each of the upper-level alignment marks in the hologram mask, and calculating the orientation and scale of the co-ordinate axes of the pattern recorded in the hologram mask with respect to the co-ordinate axes of the substantially orthogonal directions in which the lower-level alignment mark is displaced from the relative positions of the lower-level alignment mark, according to those co-ordinate axes, when it is aligned with each of the upper-level marks in the hologram mask.

For the case where the large final pattern constitutes a higher-level pattern for a multi-level structure being fabricated on the substrate surface for which the lower-level pattern or patterns have already been printed, then the method of the present invention may additionally include the step of accurately aligning each segment of the upper-level pattern in the hologram mask with respect to the lower-level pattern before it is printed it from the hologram mask onto the substrate. Aligning comprises the combination of measuring the relative position of the segment of the upper-level pattern recorded in the hologram mask with the lower-level pattern on the substrate and then displacing at least one of the hologram mask and substrate until the upper-level pattern segment and the lower-level pattern are aligned.

According to a second aspect of the invention there is provided an apparatus using TIR holography for printing a large final pattern onto a substrate bearing a layer of photosensitive material, which apparatus includes:
a) a mask containing one of each distinctive pattern segment in a plurality of pattern segments that compose the large final pattern;
b) a means for recording a hologram mask of the mask pattern;
c) a coupling element with a first face for arranging the hologram mask thereon and a second face through which an exposure beam may pass for reconstructing the pattern recorded in the hologram mask;
d) a TIR holographic lithographic system having a means for lateral positioning of the substrate relative to the hologram mask to enable the different pattern segments to be printed from the hologram mask at the respective locations on the substrate required to recompose the large final pattern, and having also exposure means for enabling the different pattern segments to be discretely reconstructed from the hologram mask by an exposure beam and printed onto the substrate.

Preferably, the coupling element is a prism or such similar refractive component that allows the exposure beam to illuminate the hologram mask through the second substrate such that it is totally internally reflected from the surface of the hologram and such that it reconstructs the mask pattern recorded in the hologram. The coupling element may alternatively be a diffractive structure such as a grating or combination of gratings on the surface or surfaces of a transparent plate or stack of plates which similarly allows the exposure beam to illuminate the hologram mask through the second substrate at an angle such that it is totally internally reflected from the surface of the hologram mask and such that it reconstructs the mask pattern recorded in the hologram mask.

Preferably, the exposure means for discretely reconstructing a particular pattern segment from the hologram mask includes means for shielding those neighbouring parts of the hologram mask that reconstruct other pattern segments in order to ensure that only the desired pattern segment is reconstructed. Such shielding means may comprise a means for blocking, reflecting or absorbing the light in the exposure beam, such as one or more opaque screens, and include also a means for arranging or positioning the blocking, reflecting or absorbing means in the exposure beam according to the particular pattern segment to be reconstructed in order that it blocks, reflects or absorbs light in the exposure beam that would otherwise illuminate those parts of the hologram mask that reconstruct neighbouring pattern segments.

When the exposure means for reconstructing a particular pattern segment in the hologram mask includes a system for scanning the exposure beam across the hologram mask, as is taught and recommended in the prior art, the means for shielding neighbouring parts of the hologram mask from the exposure beam may be achieved by interposing a means or a plurality of means for blocking, reflecting or absorbing the light in the exposure beam before, after or within the scanning system, or a combination of any of the three.

If a scanning system is used to scan the exposure beam across the hologram mask it is preferable that the local separation between the substrate and hologram mask where the exposure beam is illuminating the mask be continuously measured and the longitudinal position of the substrate relative to the hologram mask be continuously adjusted to a constant value in order that the complete pattern is accurately printed in focus onto the substrate surface.

Preferably also the means for arranging the lateral position of the substrate in relation to the hologram mask should include a translation stage or stages for displacing the substrate in at least one of two substantially orthogonal directions in the plane of the substrate.

For obtaining high-accuracy abutment, or stitching, between pattern segments printed from the hologram mask onto the substrate, the displacement of the substrate should be performed accurately. For this purpose, it is additionally desirable that the lateral positioning means for the substrate incorporate high-resolution actuators such as piezo-electric transducers, and furthermore that means be provided for accurately measuring the displacement of the substrate between the different exposures. Such a measuring means is a 3-axis interferometer system of the type well-known to those skilled in the art whose 3 measurement beams are arranged substantially in the plane of the substrate. The system's operation requires the integration of two long, mirrors that are substantially mutually orthogonal, on the substrate positioning means for reflecting the measurement beams to detectors for electronic processing. With such an interferometer system for accurately measuring the lateral displacement of the substrate, the axes of the substantially orthogonal directions in which the substrate is displaced are defined by the substantially orthogonal measurement axes of the interferometer system.

For achieving high-accuracy stitching it is additionally necessary that the displacement of the substrate take into account firstly the orientation of the co-ordinate axes of the pattern recorded in the hologram mask with respect to the co-ordinate axes of the substantially orthogonal directions in which the substrate is displaced, secondly the scales of the co-ordinate axes of the pattern recorded in the hologram mask relative to the respective co-ordinate axes of the substantially orthogonal directions in which the substrate is displaced, and thirdly the orthogonality error between the axes of the substantially orthogonal directions in which the substrate is displaced, that is the deviation from 90 of the angle between the two substantially orthogonal directions. For this purpose, means should preferably be provided for determining the orientation and scales of the co-ordinate axes of the pattern recorded in the hologram with respect to the co-ordinate axes of the substantially orthogonal directions in which the substrate is displaced, and also for determining the orthogonality error of the co-ordinate axes of the substantially orthogonal directions in which the substrate is displaced. Such a means is an alignment system of the type described in the above section on the prior art that comprises at least 3 microscopes for viewing upper-level alignment marks recorded into the hologram mask, and at least one lower-level alignment mark arranged on the lateral positioning means in the lithographic system, either provided directly on the surface of the lateral positioning means or provided on the surface of a substrate arranged on the lateral positioning means.

For the case that the final large pattern constitutes an upper-level pattern to be printed onto an existing pattern on the substrate then the apparatus of the present invention should include an alignment system on the lithographic machine consisting of, for example, two or more microscopes for accurately measuring the relative positions of each upper-level pattern segment recorded in the hologram mask with respect to lower-level pattern printed on the substrate. For this purpose it is advantageous to include alignment marks within or alongside the upper-level pattern segments recorded in the hologram mask and corresponding marks within or alongside the lower-level pattern printed on the substrate.

Preferred embodiments of the invention will now be described in greater detail with reference to the following drawings, wherein:

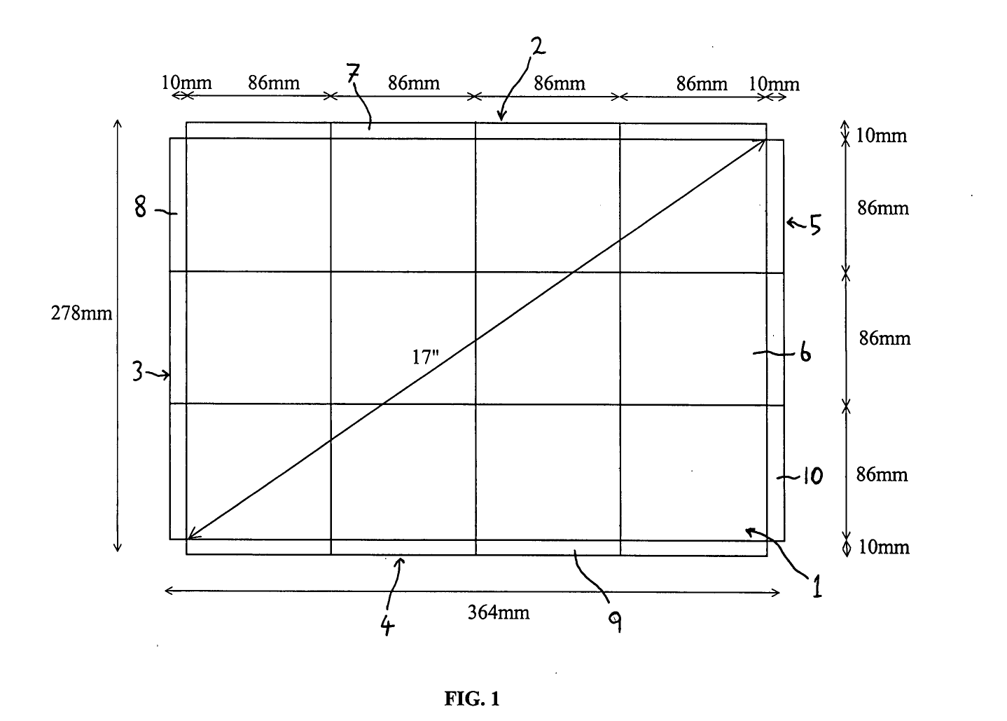

FIG. 1 shows an example of a large final pattern to be printed onto a substrate, which is decomposed into a plurality of pattern segments.

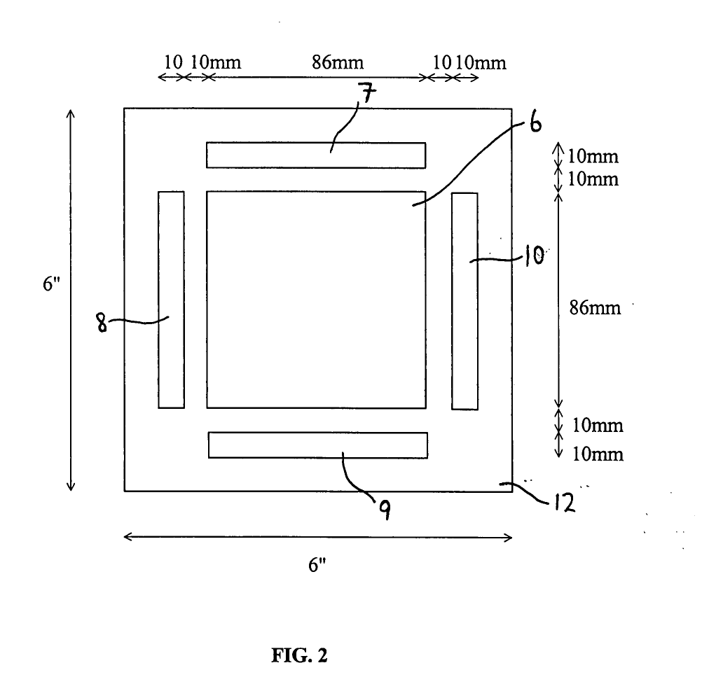

FIG. 2 shows the different pattern segments of the large final pattern arranged in a chrome mask.

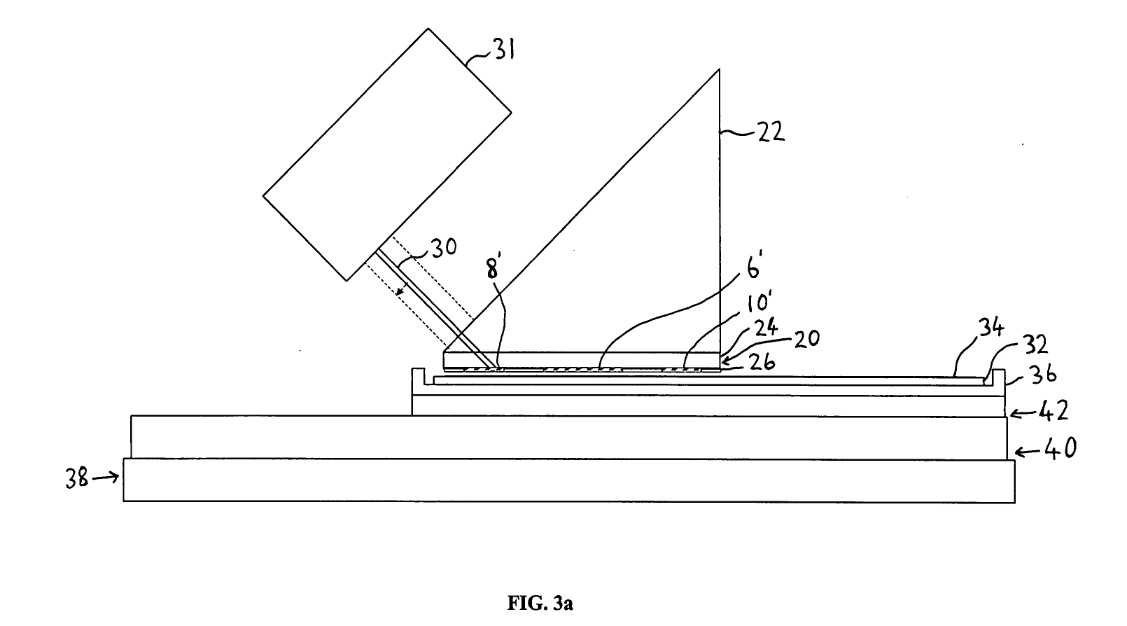

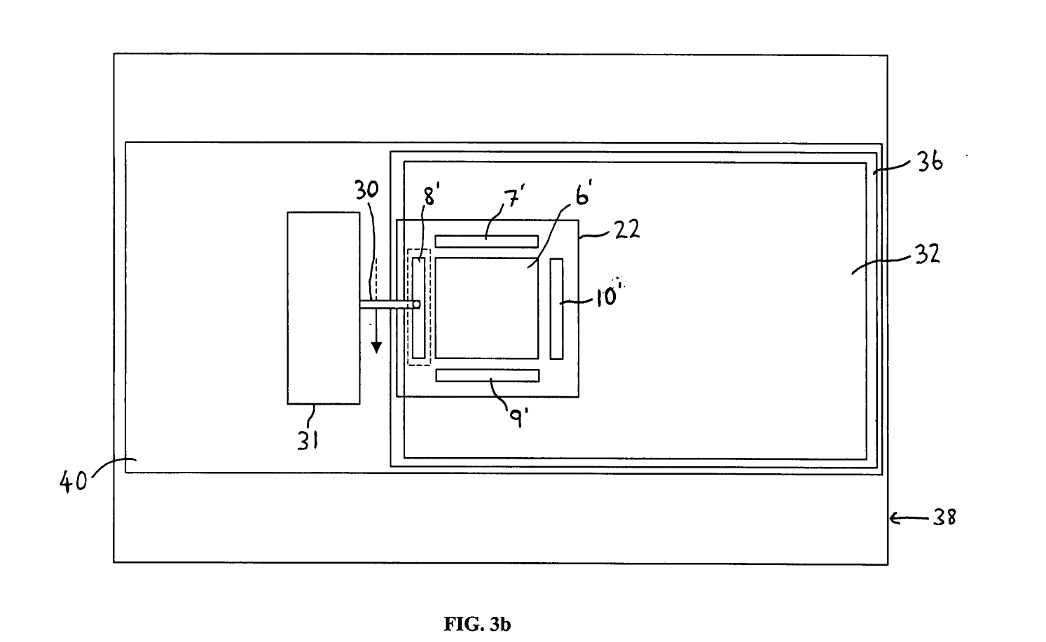

FIGS. 3a and 3b show respectively a side view and top view of a lithographic system in which a substrate is laterally positioned with respect to the hologram mask for printing a particular pattern segment from the hologram mask at a particular location on the substrate.

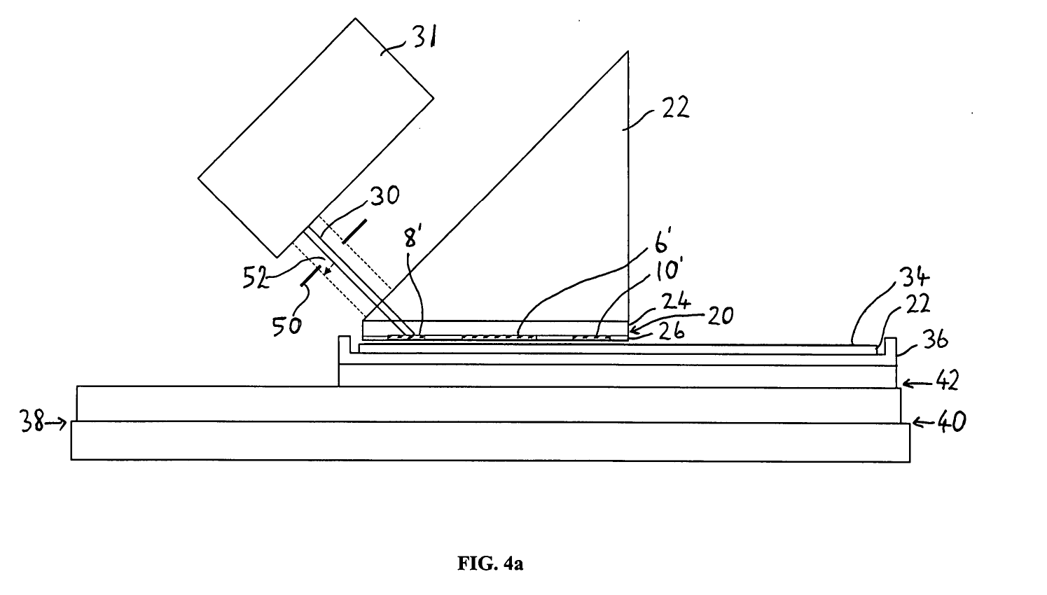

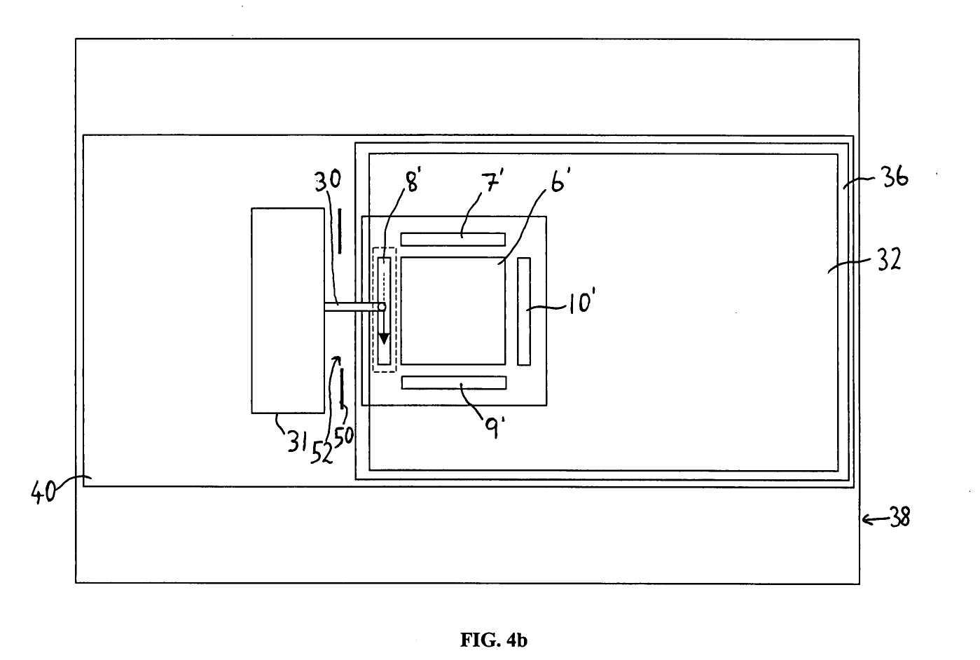

FIGS. 4a and 4b show respectively a side view and a top view of a lithographic system for discretely printing a pattern segment onto a substrate which additionally integrates an opaque screen for shielding those parts of the hologram mask that reconstruct neighbouring pattern segments.

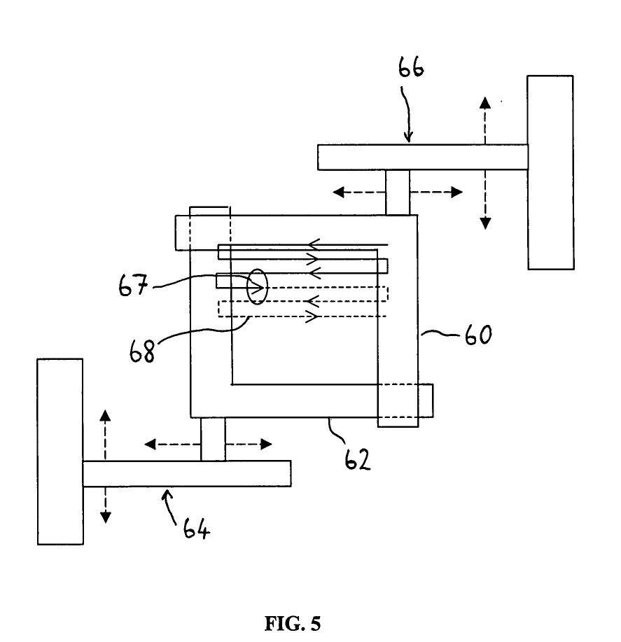

FIG. 5 shows a preferred embodiment of a means for shielding those parts of the hologram mask that reconstruct neighbouring pattern segments.

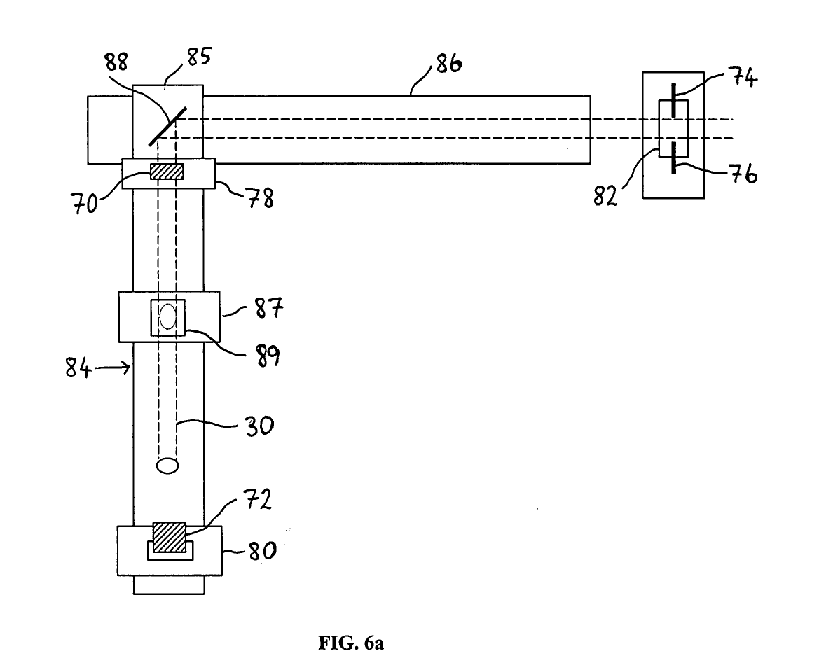

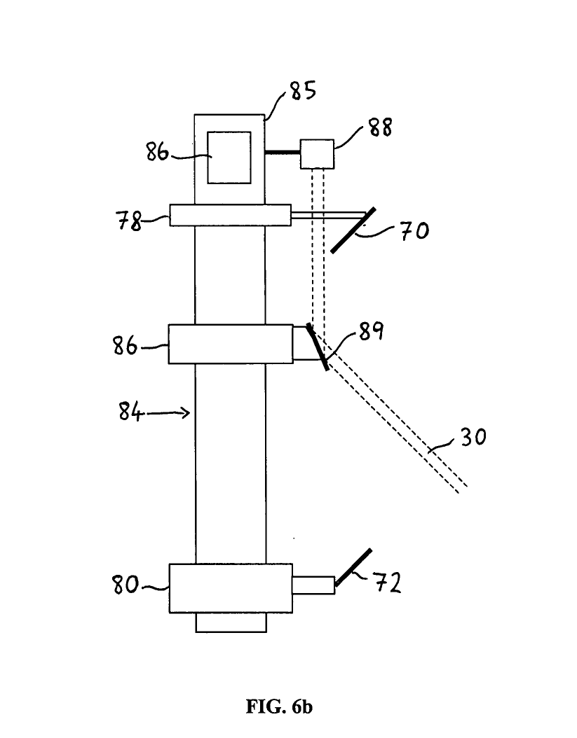

FIGS. 6a and 6b show a front view and a side view respectively of an alternative means for shielding those parts of the hologram mask that reconstruct neighbouring pattern segments, in which a part of the means is integrated within the scanning system.

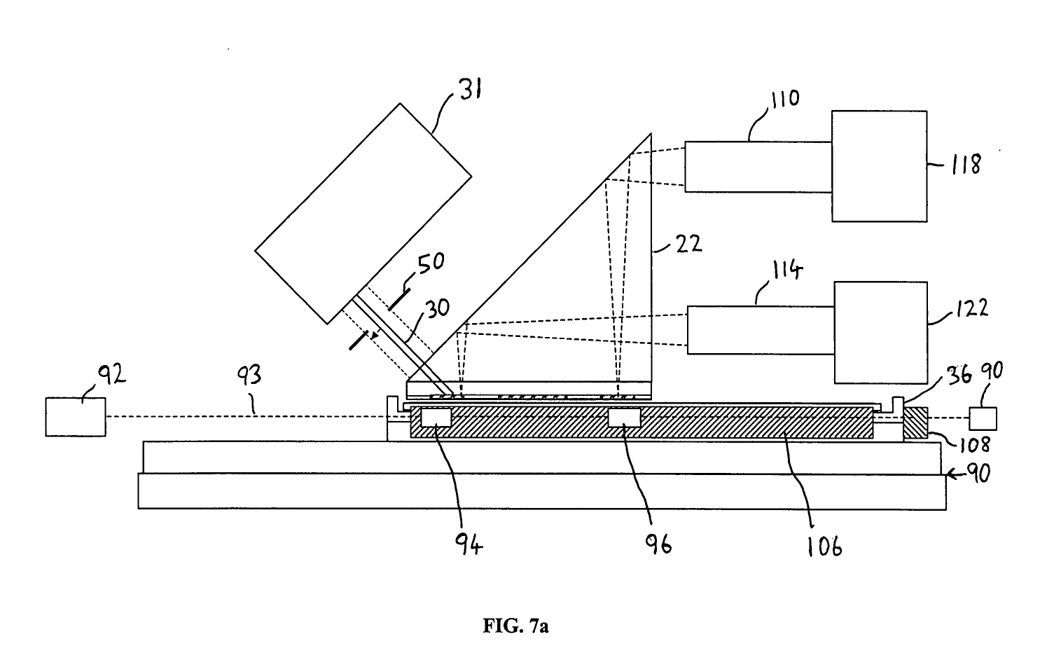

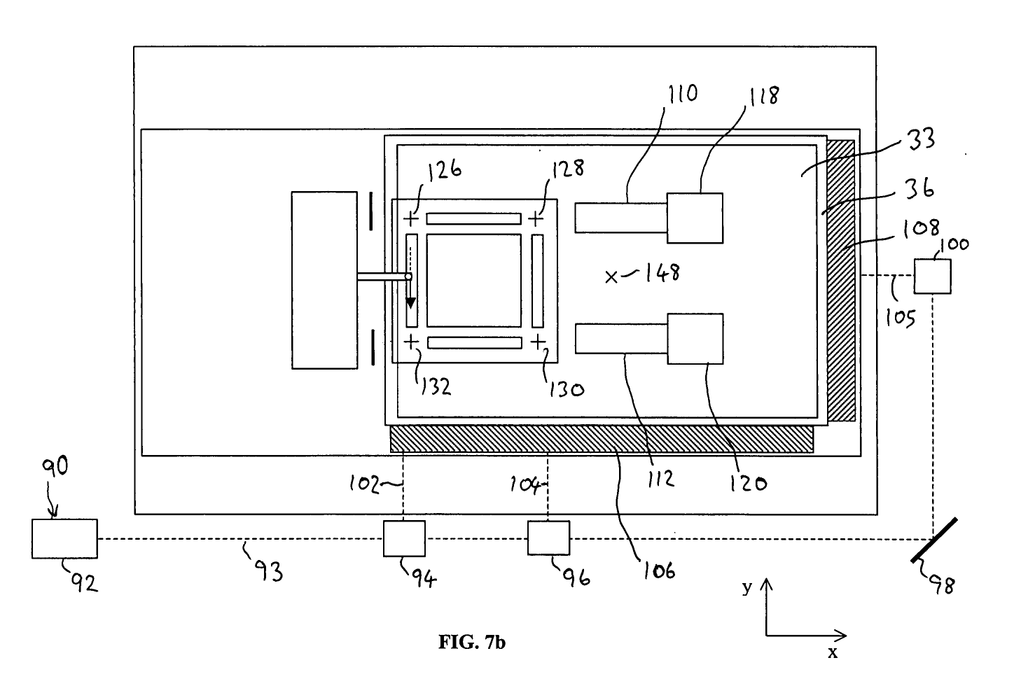

FIG. 7a and 7b show respectively a side view and top view of a preferred embodiment of the invention in which an interferometer system and alignment microscopes are additionally integrated onto the lithographic machine.

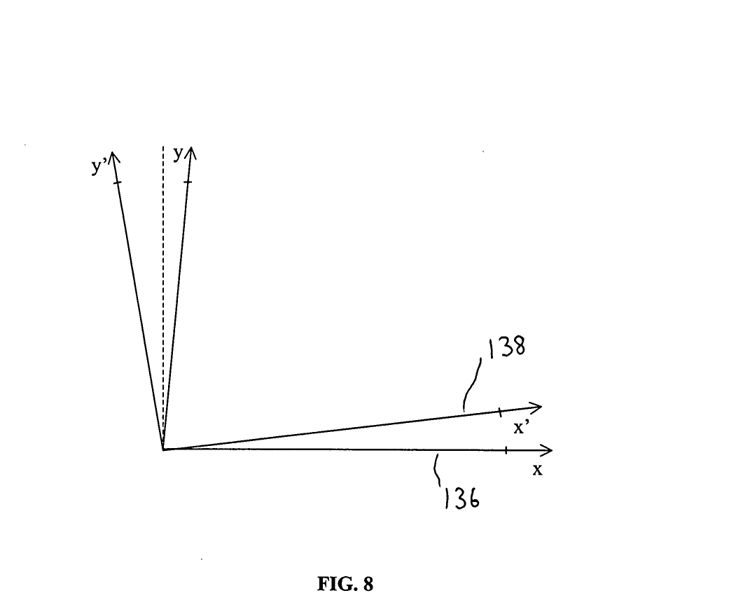

FIG. 8 illustrates the φ, Mₓ, M_{y} and ω parameters associated with the co-ordinate systems of the hologram mask and interferometer system.

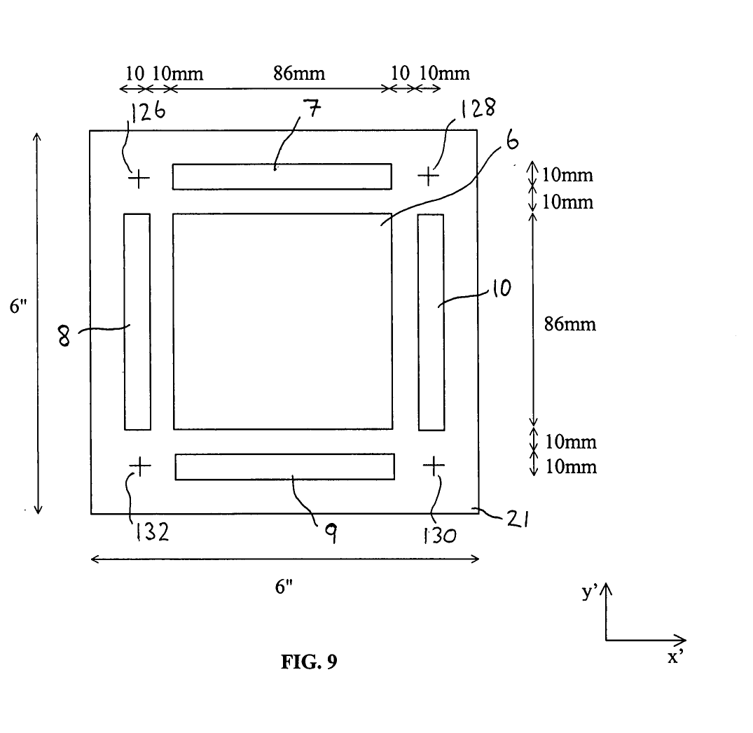

FIG. 9 shows an alternative design for the chrome mask with alignment marks added for enabling determination of the (φ, Mₓ, M_{y} and ω parameters.

Circuit patterns for liquid crystal flat panel displays typically consist of a rectangular matrix, or “active area”, of repeating picture elements, or “pixels”, containing thin-film transistors which is surrounded on its four sides by connector structures for electrically addressing the individual pixels. Because of this a display pattern may be decomposed into smaller segments of pixel and connector structures that repeat over the total pattern area. For example and with reference to FIG. 1, the active area 1 of a 17″ display pattern surrounded on its sides by four connector structures 2, 3, 4, 5 may be decomposed into a 3×4 array of a pixel segments wherein each pixel segment 6 has dimensions 86 mm×86 mm; the top and bottom connector structures 2, 4 may be respectively decomposed into 4×1 arrays of top and bottom connector segments 7, 9 wherein each top and bottom segments 7, 9 have dimensions 86 mm×10 mm; and the left and right connector structures 3, 5 may be respectively decomposed into 3×1 arrays of left and right connector segments 8, 10 wherein each left and right segments 8, 10 have dimensions 10 mm×86 mm. With reference now to FIG. 2, by arranging the patterns for a pixel segment 6, a top segment 7, a bottom segment 9, a left segment 8 and a right segment 10 in the chrome mask 12 allows the complete pattern for the 17″ diagonal display to be defined in a mask of dimensions of 6″×6″, the maximum extent of total pattern area being only 126 mm×126 mm.

FIGS. 3a and 3b show respectively a side view and a top view of a hologram mask 20 recorded from the chrome mask 12 of FIG. 2 which is in contact with the bottom face of a 45°, 45°, 90° glass prism 22. The hologram mask 20 consists of a glass substrate 24 with the hologram recorded in a layer of photopolymer 26 on its lower surface. The parts of the polymer layer 6′, 7′, 8′, 9′, 10′ recording the pixel segment 6, left and right connector segment 8, 10, and top and bottom connector segments 7, 9 respectively in the chrome mask 12 of FIG. 2 are shown. At the interface between the upper surface of the hologram substrate 24 and the prism 22 is a layer of transparent fluid 28 to enable an exposure beam 30 passing through the hypotenuse face of the prism 22 to illuminate the hologram mask 20 at the desired angle. The exposure beam 30 scans in a raster pattern through the hypotenuse face of the prism 22, illuminating the hologram mask 20 at the required angle of incidence for reconstructing the pattern recorded therein. The exposure beam is generated by an exposure system 31 including a laser source, a beam expander and a 2-axis motorised scanning system, the details of which are not illustrated here since they are well known to those skilled in the art. Below the hologram mask 20 is a display substrate 32 coated with a layer of photoresist 34 on a vacuum chuck 36. The chuck 36 is mounted to a positioning system 38 incorporating a pair of motorised translation stages 40, 42 that incorporate encoders which allow the stages to be accurately displaced substantially parallel to the edges of the display substrate 32, and whose travel ranges enable the complete 17″ display pattern to be printed onto the substrate 32. The substrate 32 is shown displaced by the motorised translation stages 40, 42 such that its lateral position with respect to the hologram mask 20 allows the left pattern segment 8 to be printed at the desired location on the substrate 32. The displacements required of the motorised translation stages 40, 42 for printing the various pattern segments onto the substrate in such a way that they are accurately stitched together may be determined empirically by first carrying out one or more test prints of the display pattern onto substrates, evaluating the resulting stitching errors between adjacent pattern segments and subsequently adjusting the displacements of the translation stages 40, 42 to compensate these errors in order to print the final 17″ display pattern onto the substrate 32. The substrate positioning system 38 may advantageously be additionally equipped with high-resolution actuators to allow more precise lateral positioning of the substrate 32 relative to the hologram mask 20. Additional axes of motion should also be provided in the substrate positioning system 38 (not shown in the figure) to allow the substrate 32 to be displaced substantially orthogonally with respect to the hologram mask 20 in order that it can be positioned in proximity and parallel to the hologram mask 20, and also so that the separation between the two may accurately adjusted during the scanning exposure for the focussing operation. Also not shown in the diagram is the focus measurement system that continuously measures the separation between the hologram mask 20 and substrate 32 where the exposure beam 30 is locally exposing the substrate 32 as the exposure beam 30 scans the hologram mask 20. As previously mentioned, the composition and operation of such focus measurement systems are adequately described in the prior art, so are not repeated here. The parameters of the motorised scanning stages in the exposure system 31 are selected in order that the extent of the scan area defined by the raster motion of the exposure beam 30 is limited to that part of the hologram mask that reconstructs the desired left pattern segment 8 (as is illustrated in the figure) while ensuring that it is uniformly exposed.

FIGS. 4a and 4b show respectively a side view and top view of another embodiment of the invention in which a blocking means in the form of an opaque screen 50 with a rectangular aperture 52 is included in the path of the exposure beam 30 before the hypotenuse of the prism 22. The plane of the screen 50 is substantially orthogonal to the path of the exposure beam 30 in order to minimise scatter of the beam from the edges of the aperture 52. This aperture 52 allows the separation of the different pattern segments 6, 7, 8, 9, 10 recorded in the hologram mask 20 to be minimised in order that the dimensions of the segments can be maximised for general applications, which advantageously minimises the time it takes to print the complete final pattern onto the substrate 32. The dimensions of the aperture 52 projected into the plane of the polymer layer 26 are just larger than the dimensions of the area of the hologram mask recording the particular pattern segment 8′ in order that scatter and diffraction of the exposure beam 30 from the edges of the aperture 52 do not also illuminate the part of the hologram mask 8′ reconstructing the pattern segment, or indeed any other pattern segment. The separations between pattern segments in the original chrome mask 12 in FIG. 2 are selected with reference to the same criteria. The exact dimensions needed can be readily calculated by those skilled in the art. To minimise the time it takes for the exposure beam 30 to print the pattern segment 8 onto the substrate 32, the parameters defining the displacements of the 2-axis motorised scanning stages in the exposure system are selected in order that the area over which the exposure beam 30 is raster scanned corresponds to the location and dimensions of the aperture in the screen and such that the integrated energy density of the light-field reconstructing the pattern segment 8 is uniform. Clearly with this embodiment of the invention, the aperture 52 in the screen 50 needs to be interchanged with equivalent apertures in equivalent screens, or at least the aperture 52 in the screen 50 displaced, and the parameters defining the scanning area of then exposure modified before the other pattern segments 6, 7, 9, 10 recorded in the hologram mask 20 are reconstructed. FIG. 5 shows an preferred embodiment of the invention in which the shielding means for enabling discrete reconstruction of the pattern segments in the hologram mask is in the form of two displaceable sets of orthogonally arranged pairs of blades 60, 62 each of which is mounted to independent 2-axis motorised translation stages 64, 66 located before the hypotenuse of the prism 22. The plane of the aperture defined by the blades 60, 62 is arranged substantially parallel to the hypotenuse face of the prism 22 in order that scatter and diffraction from the edges of the blades 60, 62 is minimised. This mechanism allows the dimensions and location of the aperture defined by the blades 60, 62 to be automatically and quickly changed for any of the pattern segments recorded in the hologram mask 20. The cross-section of the exposure beam 67 and the raster scan path 68 of the beam as it scans across the rectangular aperture defined by the blades 60, 62 are shown in the diagram. Clearly, based on this principle, other arrangements of blades before the hypotenuse face of the prism 22 are possible, such as four separate linear blades each mounted to a single-axis motorised stage such that each blade can be displaced to define the limit of one of the four edges of the scanning area illuminated by the scanning beam, such that the superposition of the four blades defines a rectangular aperture lying preferably substantially parallel with the hypotenuse face of the prism 22. With this arrangement displacement of only one, two or three of the blades may be sufficient to ensure discrete exposure of the pattern segment required, for example when the pattern segment is at an edge of the pattern recorded in the hologram mask 20.

FIGS. 6a and 6b show respectively a front view and side view of an alternative preferred embodiment of the shielding means, in which the shielding means instead comprises a system of four smaller blades 70, 72, 74, 76 each of which can be displaced by motorised translation stages 78, 80, 82. Two of the blades 70, 72 are mounted respectively to independent motorised stages 78, 80 on the scanning system 84 for the exposure beam 20 whilst the other two 74, 76 are mounted to a single motorised translation stage 82 before the scanning system 84. The exposure beam 30 is scanned in a raster pattern by a stepping displacement of motorised translation stage 85 on a rail 86 alternating with a constant velocity scan of motorised translation stage 87 on stage 85. The beam is successively reflected by two mirrors 88, 89 mounted on the translation stages 85, 87, the beam reflected from the second mirror 89 then illuminating the hypotenuse face of the prism 22. Before the scanning exposure begins, the two blades 70, 72 on the scanning system 84 are positioned by the motorised stages 78, 80 to define the left and right limits of the exposed area of the hologram mask 20 and the blade 74 before the scanning system 84 is positioned by the motorised stage 82 to define the top limit of the exposed area of the hologram mask 20, and towards the end of the exposure the blade 76 before the scanning system 84 is positioned by the motorised stage 82 to define the bottom limit of the exposed area of the hologram mask 20. As for the embodiments shown in FIGS. 4 and 5 the exact locations of the blades 70, 72, 74, 76 in this embodiment are selected to ensure that scattered and diffracted light from the blades 70, 72, 74, 76 does not illuminate the part of the hologram mask 20 reconstructing the pattern segment required, or indeed any other segment.

FIGS. 7a and 7b show respectively a side view and top view of a preferred embodiment of the invention which also integrates a 3-axis interferometer system 90 of the type well-known in the art (as is manufactured by such companies as Zygo Corporation and Hewlett-Packard Company) for allowing a very accurate displacement of a substrate on the chuck 36 relative to the hologram mask 21 in order to enhance the stitching accuracy between adjacently printed pattern segments. The system comprises a helium-neon laser 92 whose output beam 93 passes through a first beam division-detection module 94 where the beam is partially reflected and partially transmitted. The transmitted beam is incident on a second beam division-detection module 96 where again it is partially reflected and partially transmitted. The beam transmitted by the second beam division-detection module 96 is reflected by a mirror 98 and incident on a beam reflection-detection module 100 where it is totally reflected. The beams 102, 104 reflected by the beam division-detection modules 94, 96 are incident on a mirror 106 mounted alongside the chuck 36 on the substrate positioning system 38, and the beam 105 reflected by the beam reflection-detection module 100 is incident on another mirror 108 mounted substantially orthogonally to the mirror 106, also alongside the chuck 36 on the substrate positioning system 38. The upper surfaces of the mirrors 106, 108 lie below the plane of the hologram mask 21 so that the mirrors 106, 108 can displace under the hologram mask 20. Before being metallised, the surfaces of the substrates for the mirrors 106, 108 were polished to provide very good surface flatness. The beams reflected from the mirrors 106, 108 return to the respective beam division-detection and beam reflection-detection modules 94, 96, 100, where they are combined with reference beams and the resulting signals are electronically processed to determine the translational and angular displacements of the substrate 32. In combination with high-precision actuators, such as piezo-electric transducers, in the substrate positioning system 38, the interferometer system 90 allows high-accuracy displacements of a substrate on the chuck 36 relative to the hologram mask 20.

This capability though is insufficient for obtaining high stitching accuracy between pattern segments because stitching errors also depend other factors such as accurate displacement of the chuck 36 with respect to the exact dimensions of the pattern segments reconstructed by the hologram mask 21. High-stitching accuracy may though be obtained by combining the capability with the procedure outlined above in which test plates are printed and the stitching errors between adjacent pattern segments evaluated and subsequently compensated by adjusting the displacements of the substrate positioning system 38 when printing the various pattern segments in the final pattern. But this is a time-consuming and awkward approach. A more desirable approach is to accurately determine beforehand the values of the fundamental parameters that give rise to the aforementioned stitching errors and to displace a substrate on the chuck 36 using the positioning system 38 according to these values. The parameters concerned are the following: i) the angle, (φ, of the machine's co-ordinate system, as defined by the interferometer system (specifically, the axis of the mirror 106 from which two of the interferometer laser beams are reflected), with respect to the co-ordinate system of the pattern recorded in the hologram mask 21, ii) the magnification, or scaling, factors of the x and y axes of the machine's co-ordinate system, Mₓ and M_{y}, with respect to the respective axes of the hologram mask's co-ordinate system, as defined by the axes of the mask pattern recorded in the hologram mask, and iii) the orthogonality error, ω, of the machine's co-ordinate system, that is, the deviation from 90° of the angle between the two mirrors 106, 108. These different parameters are illustrated in FIG. 8, where the x and y axes are those of the machine co-ordinate system 136 and the x′ and y′ axes are those of the hologram mask co-ordinate system 138. They may be evaluated empirically by printing test patterns like before and then analysing the resulting stitching errors. This method, though, is complex and time consuming.

A preferred method for evaluating the φ, Mₓ, M_{y} and ω parameters is to use the alignment system that is generally present on lithographic equipment based on TIR holography. With reference again to FIGS. 7a and 7b, four alignment microscopes of such an alignment system 110, 112, 114, 116, each mounted to one of four 2-axis translation stages 118, 120, 122, 124, are positioned in order to view upper-level alignment marks 126, 128, 130, 132 at the four corners of the pattern recorded in the hologram mask 21. This hologram mask 21 was recorded from the chrome mask 13 illustrated in FIG. 9 which contains the same configuration of pattern segments 6, 7, 8, 9, 10 as the chrome mask 12 illustrated in FIG. 2, but has additionally four upper-level alignment marks 140, 142, 144, 146 included at the four corners of the pattern, arranged so that the two alignment marks on any edge of the pattern lie parallel to either the x′-axis or y′-axis of the mask co-ordinate system as defined at the bottom of FIG. 9. The upper-level marks have been recorded into the hologram mask 21 using just an object-beam illumination of the marks 140, 142, 144, 146 in the chrome mask 21. In another embodiment of the invention the upper-level alignment marks (and lower-level alignment mark on the substrate) may be features within the circuit patterns. Other techniques may also be used. Referring back to FIG. 7b, a substrate 33 having a lower-level alignment mark 148 located at the centre of its upper surface (which has been printed and subsequently etched into a thin layer of metal on the surface) is placed on the vacuum chuck 36. Using the substrate positioning system 38, the substrate 33 is then longitudinally displaced so that it is in proximity and parallel to the hologram mask 21 and displaced laterally so that the lower-level alignment mark 148 on the substrate 33 is below the upper-level alignment marks 128 in the hologram mask 21. Using the alignment microscope 110 viewing this particular mark 128 and the high-resolution actuators in the substrate positioning system 38, the lower-level alignment mark 148 on the substrate 33 is next accurately aligned with the upper-level alignment mark 128 in the hologram mask 21. The location of the substrate according to the three measurement channels of the interferometer system 90 is stored. This procedure is repeated for the other 3 upper-level alignment marks 126, 130, 132 in the hologram mask 21 to yield a total of 4 sets of three interferometer readings which together define the relative locations of the four upper-level alignment marks 126, 128, 130, 132 in the hologram mask 21 with respect to the co-ordinate system of the interferometer system 90 having x and y axes as defined at the bottom of FIG. 7b. Processing this data with reference to the design locations of the upper-level alignment marks in the chrome mask 13 allows each of the φ, Mₓ, M_{y} and ω parameters to be calculated (specifically, the φ value may be calculated by determining the offset in the y direction according to the machine's co-ordinate system of two upper-level marks which have the same y′ co-ordinate according to the mask co-ordinate system, such as marks 140, 142, and dividing the offset value by the separation of the two marks 140, 142 in the x′ direction; the Mₓ value may be calculated simply by dividing the separation in the x direction, as given by the machine's co-ordinate system, of two upper-level marks having the same y′ co-ordinate in the mask, such as marks 140, 142, by their separation according to the mask co-ordinate system; and correspondingly for the M_{y} value; and the ω value may be directly calculated from the positions according to the machine's co-ordinate system of 3 upper-level marks in the mask whose adjoining lines subtend a right-angle, such as marks 140, 146, 144). In fact, any 3 sets of the interferometer readings are sufficient for calculating the various parameters, but a fourth set allows reduction of measurement errors by using appropriate processing algorithms, as would be familiar to somebody skilled in the art.

Applying this methodology and the values of φ, Mₓ, M_{y} and ω thus determined to the case where stitching together two pattern segments requires the substrate to be accurately stepped to co-ordinates Dₓ and D_{y} with respect to the hologram mask's co-ordinate system, then the co-ordinates Sₓ and S_{y} to which the substrate 33 is needed to be stepped with respect to the interferometer's co-ordinate system are given by:
Sₓ=MₓDₓ cosφ+M_{y}D_{y} sin(φ+ω);
S_{y}=M_{y}D_{y} cosφ−MₓDₓ sinφ.

Using these equations for all the pattern segments to be printed enables the complete 17″ display pattern to be printed with high stitching accuracy between all the pattern segments.

In order to further enhance the stitching accuracy of the lithographic system, especially for the case where the flatness of the two interferometer mirrors 106, 108 is not so good, the above expressions describing the displacements of the substrate 33 may be modified by including extra terms that compensate possible errors in the flatness of the mirrors 106, 108. These errors may have magnitude up to 1 micron or more, depending on the precision with which the mirrors were manufactured. The values required for every position Dₓ, D_{y} may be determined either empirically by printing and stitching test patterns and evaluating and analysing the resulting errors or preferably by characterising the mirror flatness using an independent and reliable measurement system and introducing the measurement data into the software controlling the displacement of the substrate positioning system. Since non-flatness of the mirrors 106, 108 without such compensation can result in rotation of the pattern printed on the substrate between steps, the above expressions describing the stepping distance, S_{y}, required of the substrate in the y direction according to the interferometer system need to be different for the 2 beam division-detection modules 94, 96, that is the expression for S_{y} should rather be replaced by separate expressions for the two modules 94, 96:
Sₓ=MₓDₓ cosφ+M_{y}D_{y} sin(φ+ω)+fₓ(−D_{y});
S1_{y}=M_{y}D_{y} cosφ−MₓDₓ sinφ+f_{y}(−Dₓ−t).
S2_{y}=M_{y}D_{y} cosφ−MₓDₓ sinφ+f_{y}(−Dₓ+t).
where S1_{y} and S2_{y} are the positions required of the substrate according to the respective division-detection modules 94, 96, the functions fₓ( ), f1_{y}( ) and f2_{y}( ) describe the non-flatness along the lengths of the mirrors 106, 108 respectively and t is half the separation between the two interferometer beams 102, 104 at the mirror 106.

1. A method for printing a large final pattern onto a substrate bearing a layer of photosensitive material, which method includes the steps of:
a) decomposing the large final pattern into a plurality of pattern segments, at least one of which is repeated one or more times around the large final pattern;
b) providing a mask with a pattern having a first co-ordinate system in which is arranged one of each distinct pattern segment present in the plurality of pattern segments of the decomposed large final pattern;
c) recording a hologram mask of the mask pattern;
d) arranging the hologram mask on the first face of a coupling element so that the mask pattern recorded therein may be reconstructed by an exposure beam passing through a second face of the coupling element;
e) providing a TIR holographic lithography machine with an exposure system including a light source a scanning system for discretely reconstructing using a scanning illumination beam the individual pattern segments recorded in the hologram mask and with a substrate positioning system having a second co-ordinate system for laterally displacing the substrate with respect to the hologram mask;
f) arranging the hologram mask and coupling element in the lithographic machine;
g) arranging the substrate on the substrate positioning system in the lithographic machine;
h) displacing the substrate to a first lateral position with respect to the hologram mask such that a first pattern segment recorded in the hologram mask may be printed onto the substrate at a first location corresponding to that required in the large final pattern;
i) discretely reconstructing the first pattern segment recorded in the hologram mask and printing it at the first location on the substrate;
j) displacing the substrate to a second lateral position in relation to the hologram mask such that the first or another pattern segment may be printed from the hologram mask at a second location on the substrate corresponding to that required in the large final pattern;
k) discretely reconstructing said first or another pattern segment from the hologram mask and printing it at the second location on the substrate;
l) repeating steps j) and k) for all the different pattern segments recorded in the hologram mask, printing them at them at the required locations on the substrate for recomposing the large final pattern, until the large final pattern has been printed onto the substrate.

2. A method according to any of the claim 1, wherein providing a lithographic machine with an exposure system for discretely reconstructing the pattern segments recorded in the hologram mask includes providing a shielding system in the exposure system for shielding from the scanning illumination beam those parts of the hologram mask that reconstruct pattern segments neighbouring the pattern segment to be reconstructed, and wherein the steps of discretely reconstructing individual pattern segments recorded in the hologram mask includes shielding from the scanning illumination beam those parts of the hologram mask that reconstruct neighbouring pattern segments.

3. A method according to claim 2, wherein the step of providing a shielding system comprises providing a screen or screens with an aperture or apertures and wherein the step of shielding neighbouring pattern segments from the scanning illumination beam comprises interposing said screen or screens with an aperture or apertures between the scanning system and the second face of the coupling element so that light in the scanning illuminate beam that would otherwise reconstruct neighbouring pattern segments is blocked by said screen or screens.

4. A method according to claim 2, wherein the step of providing a shielding system comprises interposing at least one displaceable blade between the scanning system and the second face of the coupling element and the step of shielding neighbouring pattern segments from the scanning illumination beam comprises displacing the blade or blades such that the light in the scanning illumination beam that would otherwise reconstruct neighbouring pattern segments is blocked by said blade or blades.

5. A method according to claim 2, wherein the step of providing a shielding system comprises interposing at least one displaceable blade before or within the scanning system and the step of shielding neighbouring pattern segments from the scanning illumination beam comprises displacing the blade or blades such that the light in the scanning illumination beam that would otherwise reconstruct neighbouring pattern segments is blocked by said blade or blades.

6. A method according to claim 1 including the additional step of measuring at least one of the angle and magnification factors of the second co-ordinate system with respect to the first co-ordinate system of the pattern recorded in the hologram mask and the orthogonality error of the second co-ordinate system, and wherein displacing the substrate to a first or another lateral position with respect to the hologram mask in order to print a first or another pattern segment onto the substrate is performed according to said measured values for the angle, magnification factors and orthogonality error.

7. A method according to claim 6, wherein the method for measuring at least one of the angle, magnification factors and orthogonality error is by successively aligning a lower-level alignment mark arranged on the substrate positioning system with respect to at least two upper-level alignment marks included in the pattern recorded in the hologram mask using an alignment system included on the lithographic machine, and calculating said value or values from the positions of the substrate positioning system after each alignment according to the second co-ordinate system and the locations of the upper-level alignment marks in the mask according to the first co-ordinate system.

8. A method according to claim 7, wherein the lower-level alignment mark arranged on the substrate positioning system in the lithographic machine is either arranged directly on the surface of the substrate positioning system, or alternatively is on the surface of a plate that is arranged on the substrate positioning system.

9. A method according to claim 7, wherein the upper-level alignment marks recorded in the hologram mask are not recorded holographically by an object-beam exposure of alignment marks included in the mask and a reference-beam exposure, but only by an object-beam exposure of alignment marks included in the mask.

10. A method according to claim 6, wherein the substrate positioning system includes an interferometer system having two substantially orthogonal mirrors the flatness of which have been previously evaluated and represented by flatness data, and wherein displacing the substrate to a first or another lateral position with respect to the hologram mask additionally takes into account said flatness data, for the purpose of providing high stitching accuracy between the pattern segments printed on the substrate.

11. An apparatus for printing a large final pattern onto a substrate bearing a first layer of photosensitive material, which apparatus includes:
a) a mask with a pattern having a first co-ordinate system in which is arranged one of each distinct pattern segment present in a plurality of pattern segments that compose the large final pattern;
b) a means for recording a hologram mask of the mask pattern;
c) a coupling element with a first face for arranging the hologram mask thereon and a second face through which an illumination beam may pass for reconstructing the mask pattern recorded in the hologram mask;
d) a TIR holographic lithographic machine for reconstructing the mask pattern from the hologram mask and coupling element arranged thereon with an exposure means including a light source and a scanning means for discretely reconstructing with a scanning illumination beam the individual pattern segments recorded in the hologram mask and printing them onto the substrate, and a substrate positioning means having a second-co-ordinate system for laterally displacing the substrate with respect to the hologram mask in order that the individual pattern segments recorded in the hologram mask can be printed at the required locations on the substrate for composing the large final pattern.

12. An apparatus according to claim 11, wherein the exposure means in the lithographic machine for discretely reconstructing with a scanning illumination beam individual pattern segments in the hologram mask further includes a shielding means for shielding from the scanning illumination beam those parts of the hologram mask that reconstruct neighbouring pattern segments.

13. An apparatus according claim 12, wherein said shielding means comprises at least one screen with an aperture therein for interposing between the scanning means and the second face of the coupling element such that the light in the scanning illumination beam that discretely reconstructs the individual pattern segment passes through the aperture in the screen whereas the light in the scanning illumination beam that which would otherwise reconstruct neighbouring pattern segments is blocked by the screen.

14. An apparatus according to claim 12, wherein said shielding means comprises at least one displacing means having a blade mounted thereon interposed between the scanning means and the second face of the coupling element such that the blade or blades can be displaced to block light in the scanning illumination beam that would otherwise reconstruct neighbouring pattern segments.

15. An apparatus according to claim 12, wherein said shielding means includes at least one displacing means having a blade mounted thereon interposed before or within the scanning means such that the blade or blades can be displaced to block light in the scanning illumination beam that would otherwise reconstruct neighbouring pattern segments.

16. An apparatus according to claim 11 which additionally includes a means for measuring at least one of the angle and magnification factors of the second co-ordinate system of the substrate positioning means with respect to the first co-ordinate system of the pattern recorded in the hologram mask arranged on the lithographic machine and the orthogonality error of the second co-ordinate system, and wherein the substrate displacing means displaces the substrate with respect to the hologram mask according to said measured value or values.

17. An apparatus according to claim 16 wherein said means for measuring at least one of the angle, magnification factors and orthogonality error comprises at least two upper-level alignment marks included in the mask pattern for recording into the hologram mask, a lower-level alignment mark arranged or for arranging on the substrate positioning means, an alignment system included on the lithographic machine for aligning said lower-level alignment arranged on the substrate positioning means with respect to each of the upper-level alignment marks recorded in the hologram mask, and a means for calculating at least one of the angle, magnification factors and orthogonality error from the positions of the substrate positioning system after said alignments according to the second co-ordinate system and from the locations of the upper-level alignment marks included in the pattern recorded in the hologram mask according to the first co-ordinate system.

18. An apparatus according to claim 17, wherein each of the upper-level alignment mark recorded in the hologram mask are not recorded holographically using both an object beam exposure of the respective alignment mark included in the mask and a reference beam exposure, but rather using solely an object beam exposure of the respective alignment mark in the mask.

19. An apparatus according to claim 17, wherein the lower-level alignment mark is either arranged on the surface of the substrate positioning system or alternatively is on the surface of a plate or other carrier for arranging on the substrate positioning system.

20. An apparatus according to claim 11, wherein the substrate positioning means includes an interferometer system having two substantially orthogonal interferometer mirrors and the second co-ordinate system is defined by the interferometer system.
